(19) United States
(12) Patent Application Publication
(10) Pub. No.: US 2004/0130033 A1
(43) Pub. Date: Jul. 8, 2004

(54) Semiconductor device

(75) Inventors: Takeshi Masamitsu, Hyogo (JP); Takeru Matsuoka, Tokyo (JP); Takao Kamoshima, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/678,165

(22) Filed: Oct. 6, 2003

(30) Foreign Application Priority Data
Dec. 27, 2002 (JP) 2002-381040

(51) Int. Cl. H01L 23/48

(52) U.S. Cl. 257/760

(57) ABSTRACT

A semiconductor device has a substrate 1, a metal wiring 3 formed on the substrate 1 and covered with the films of a high-melting-point metal 2 and 4 immediately above and below and an interlayer insulating film 5 formed by a plasma CVD method so as to cover the metal wiring 3.

### BACKGROUND OF THE INVENTION

1. Field of the Invention

The present invention relates to a semiconductor device having an interlayer insulating film by a plasma CVD method so as to cover a metal wiring, and a method of manufacturing such a semiconductor device.

2. Background Art

Concurrent with the downsizing of semiconductor devices, increase in the layers of wirings and the miniaturization of wirings have proceeded, and spaces between wirings have narrowed. Conventionally, the process using the combination of SOG (spin on the glass) and etching back has been used for forming an interlayer insulating film of an inter-wiring space. However, the use of this process for forming an interlayer insulating film of an inter-wiring space beyond the 0.25-μm generation is difficult. Therefore, the process using the combination of HDP-SIO (high-density plasma SiO) and CMP (chemical mechanical polishing) has increasingly been used.

In this process, an Al wiring is first formed on a substrate as a metal wiring. Next, an SiO₂ film is formed as an interlayer insulating film by a high-density plasma CVD method so as to cover the Al wiring. Then, an SiO₂ film is formed by a plasma CVD method using tetraethoxysilane (TEOS) and O₂ gas as the reaction gas, and is planarized by a CMP method. The same processes are repeated to multiply the wiring structure.

In the plasma CVD method, in order to improve burying properties, rounding is performed using sputter etching with Ar atoms during film formation. When the Ar atoms impinge a film to be etched, heat is generated. Thereby, the temperature in the vicinity of the metal wiring is elevated during the formation of the interlayer insulating film. Then, the metal wiring is expanded by the heat. When the temperature lowers after the formation of the interlayer insulating film, the metal wiring shrinks producing voids in the metal wiring, and the side is hollowed out.

### SUMMARY OF THE INVENTION

The present invention was devised to solve the above-described problems. The object of the present invention is to provide a semiconductor device that can minimize the thermal expansion of the metal wiring when an interlayer insulating film is formed by a plasma CVD method so as to cover the metal wiring, thus preventing the production of voids in the metal wiring; and a method of manufacturing such a semiconductor device.

According to one aspect of the present invention, a semiconductor device has a substrate, a metal wiring formed on the substrate and covered with the films of a high-melting-point metal immediately above and below and an interlayer insulating film formed by a plasma CVD method so as to cover the metal wiring.

Other and further objects, features and advantages of the invention will appear more fully from the following description.

### BRIEF DESCRIPTION OF THE DRAWINGS

FIG. 1 shows a method of manufacturing a semiconductor device according to the first embodiment of the present invention.

FIG. 2 shows a method of manufacturing a semiconductor device according to the second embodiment of the present invention.

FIG. 3 shows a method of manufacturing a semiconductor device according to the third embodiment of the present invention.

FIG. 4 shows a method of manufacturing a semiconductor device according to the fourth embodiment of the present invention.

FIG. 5 shows a method of manufacturing a semiconductor device according to the fifth embodiment of the present invention.

### DETAILED DESCRIPTION OF THE PREFERRED EMBODIMENTS

First Embodiment

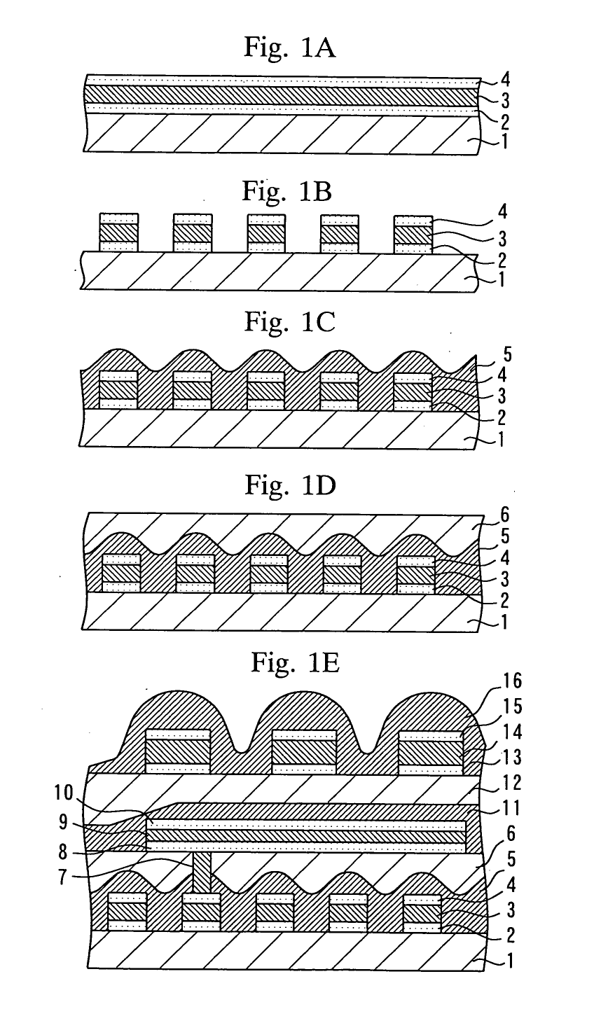

FIG. 1 shows a method of manufacturing a semiconductor device according to the first embodiment of the present invention. First, as FIG. 1A shows, a Ti film 2, which is the film of a high-melting-point metal; an Al wiring 3, which is a metal wiring; and a Ti film 4, which is the film of a high-melting-point metal are sequentially deposited on a substrate 1 consisting of Si or the like. At this time reactive layers are formed in the interfaces between the Ti film 2 and the Al wiring 3, and the Al wiring 3 and the Ti film 4. The thickness of each of the Ti films 2 and 4 is about 2.0 nm to about 5.0 nm.

Next, as FIG. 1B shows, the Ti film 2, the Al wiring 3, and the Ti film 4 are selectively etched using photolithography or the like. Thereby, the Al wiring 3 covered with Ti films 2 and 4 immediately above and below thereof, respectively, is formed. In other words, the Al wiring 3 whose upper surface is covered with the directly contacting Ti film 2, and whose lower surface is covered with the directly contacting Ti film 4 is formed.

Then, as FIG. 1C shows, an SiO₂ film is formed by a high-density plasma CVD method so as to cover the Al wiring 3 to form an HDP-SIO film 5, which is an interlayer insulating film. Here, the HDP-SIO film 5 buries the steps formed by the Ti films 2, 4 and the Al wiring 3. Specifically, the thickness of the HDP-SIO film 5 is made thicker than the total thickness of the Ti films 2, 4 and the Al wiring 3. Here, the high-density plasma CVD method is a method using SiH₄ gas and O₂ gas as reactive gases, and impressing a bias voltage to cause a high-density plasma reaction to form a film. In this film-forming method, deposition and sputter etching proceed simultaneously, and the shoulders of the steps are etched off by the impingement of Ar atoms. Thereby, the cross section in the vicinity of the surface of the HDP-SIO film 5 becomes nearly triangular as FIG. 1C shows.

Next, as FIG. 1D shows, an SiO₂ film 6 is formed on the entire surface of the HDP-SIO film 5 by a plasma CVD method using TEOS and O₂ gas as reactive gases. The SiO₂ film 6 succeeds the surface irregularity of the underlying HDP-SIO film 5. Therefore, planarization is performed by CMP.

As FIG. 1E shows, similar wiring structures are sequentially formed on the planarized SiO₂ film 6. A contact hole is formed through the HDP-SIO film 5 and the SiO₂ film 6, which is filled with a metal to form a contact plug 7. Then, an Al wiring 9 covered with Ti films 8 and 10 immediately above and below, respectively, on the SiO₂ film 6. Next, an HDP-SIO film 11 is formed by a high-density plasma CVD method so as to cover the Al wiring 9. Then, an SiO₂ film 12 is formed thereon by a plasma CVD method using TEOS and O₂ gas as reactive gases, and is planarized by CMP. Then, an Al wiring 14 covered with Ti films 13 and 15 immediately above and below, respectively, which is the uppermost-layer wiring, is formed. Next, an HDP-SIO film 16 is formed as a passivation film by a high-density plasma CVD method so as to cover the Al wiring 14. Thereby, a three-layer wiring structure is formed.

Using the method of manufacturing a semiconductor device as described above, a semiconductor device having an Al wiring 3 covered with Ti films 2 and 4 immediately above and below, and an HDP-SIO film 5 formed by a plasma CVD method so as to cover the Al wiring 3 can be obtained. In this semiconductor device, since a reactive layers are formed in the interfaces between the Ti film 2 and the Al wiring 3, and the Al wiring 3 and the Ti film 4, and the bonding force thereof is strong, the migration of metal atoms of the Al wiring 3 caused by heat generated when the HDP-SIO film 5 is formed by a high-density plasma CVD method can be inhibited. In other words, since the Al wiring 3 is strongly bonded to the Ti films 2 and 4, which are the films of a heat-resistant high-melting-point metal, the thermal expansion of the Al wiring 3 when the HDP-SIO film 5 is formed by a high-density plasma CVD method can be inhibited. Therefore, the occurrence of voids in the Al wiring 3 can be prevented.

Here, in the above-described first embodiment, although the interlayer insulating film is formed by a high-density plasma CVD method, the similar effects can be obtained when the interlayer insulating film is formed by ordinary plasma CVD method. This is because although heat generation due to sputter etching of Ar atoms during film formation is less than heat generation by the high-density plasma CVD method, the problem of the occurrence of voids in the metal wiring still exists even when the interlayer insulating film is formed by the plasma CVD method.

The first embodiment may also be a constitution wherein a TiN film is formed as a barrier metal underneath the Ti film 2 or on the Ti film 4. However, in the constitution wherein the TiN film is formed between the Al wiring 3 and the Ti film 2, or between the Al wiring 3 and the Ti film 4, the effect of the first embodiment cannot be obtained because TiN little reacts with Al.

Second Embodiment

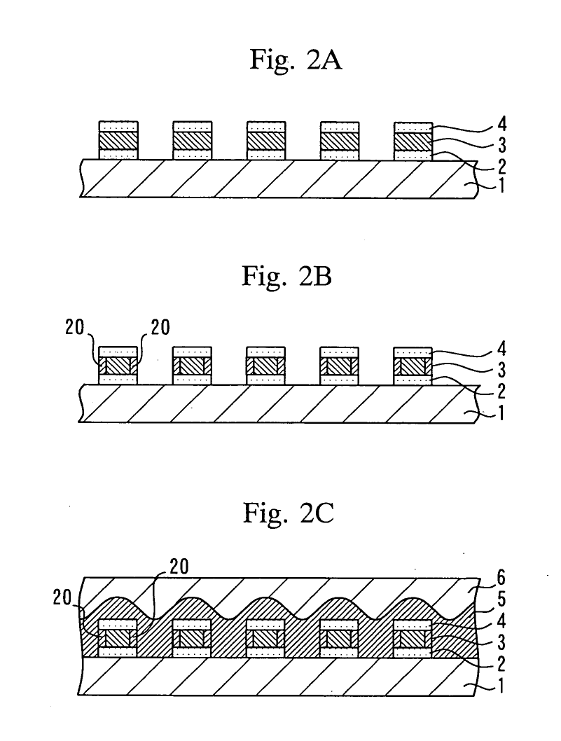

FIG. 2 shows a method of manufacturing a semiconductor device according to the second embodiment of the present invention. The same constituents as shown in FIG. 1 are denoted by the same reference numerals, and the description thereof will be omitted. First, as FIG. 2A shows, an Al wiring 3 covered with Ti films 2 and 3 immediately above and below, respectively, is formed on a substrate 1.

Next, as FIG. 2B shows, annealing is performed in a nitrogen atmosphere to nitrrogenize the side of the Al wiring 3 to form an AlN film 20, which is an Al compound layer. A part of Ti films 2 and 3, which are barrier metals, is also nitrogenized.

Then, as FIG. 2C shows, an HDP-SIO film 5, which is an interlayer insulating film, is formed by a high-density plasma CVD method so as to cover the Al wiring 3. Furthermore, an SiO₂ film 6 is formed by a plasma CVD method using TEOS and O₂ gas as reactive gases, and planarized by CMP. Then similar wiring structures are sequentially formed thereon, although the description thereof will be omitted here.

By using the method of manufacturing a semiconductor device as described above, there is obtained a semiconductor device having a substrate 1, an Al wiring 3 formed on the substrate 1; AlN layers 20 formed on the sides of the Al wiring 3; and an HDP-SIO film 5 formed by a plasma CVD method so as to cover the Al wiring 3 and the AlN layers 20. In this semiconductor device, since the AlN layers 20, which are hard films, are formed on the sides of the Al wiring 3, the thermal expansion of the Al wiring 3 when the HDP-SIO film 5 is formed by a high-density plasma CVD method can be inhibited. Therefore, the occurrence of voids in the Al wiring 3 can be prevented.

Here, in the above-described second embodiment, although the interlayer insulating film is formed by a high-density plasma CVD method, the similar effects can be obtained when the interlayer insulating film is formed by ordinary plasma CVD method. The similar effects can also be obtained when TiN films are used in place of the Ti films 2 and 4, which are barrier metals. Furthermore, in the above-described second embodiment, although the AlN films 20 are formed on the sidewalls of the Al wiring 3 by annealing in a nitrogen atmosphere, the similar effects can be obtained when the sidewalls of the Al wiring 3 are oxidized by annealing in an oxygen atmosphere to form aluminum oxide films as Al compound layers.

Third Embodiment

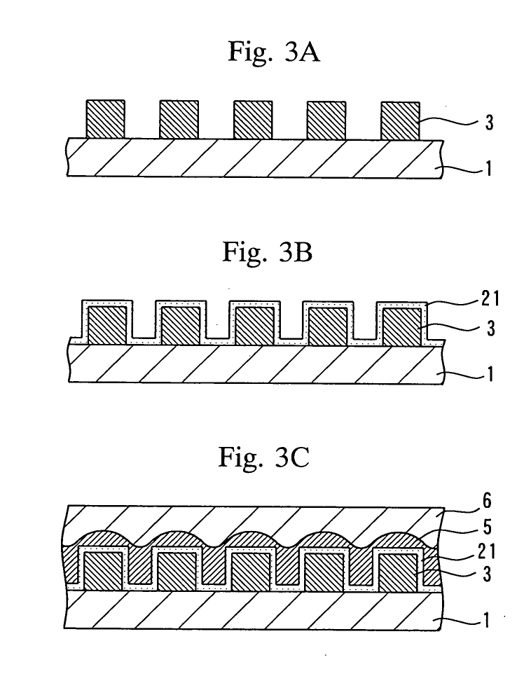

FIG. 3 shows a method of manufacturing a semiconductor device according to the third embodiment of the present invention. The same constituents as shown in FIG. 1 are denoted by the same reference numerals, and the description thereof will be omitted. First, as FIG. 3A shows, an Al wiring 3 is formed on a substrate 1.

Next, as FIG. 3B shows, an SiON film 21 is formed as a buffer layer so as to cover the Al wiring 3. The thickness of the SiON film 21 is 50 to 200 nm.

Then, as FIG. 3C shows, an HDP-SIO film 5, which is an interlayer insulating film, is formed by a high-density plasma CVD method on the SiON film 21. Furthermore, an SiO₂ film 6 is formed by a plasma CVD method using TEOS and O₂ gas as reactive gases, and planarized by CMP.

By using the method of manufacturing a semiconductor device as described above, there is obtained a semiconductor device having a substrate 1, an Al wiring 3 formed on the substrate 1; an SiON layer 21 formed so as to cover the Al wiring 3; and an HDP-SIO film 5 formed by a plasma CVD method on the SiON layer 21. In this semiconductor device, since the Al wiring 3 is covered with the SiON layer 21, the thermal expansion of the Al wiring 3 when the HDP-SIO film 5 is formed by a high-density plasma CVD method can be physically inhibited. Therefore, the occurrence of voids in the Al wiring 3 can be prevented.

The provision of the SiON layer 21, which is a buffer layer, the shoulders of the Al wiring 3 can also be protected from rounding due to sputter etching of Ar atoms when the HDP-SIO film 5 is formed by a high-density plasma CVD method. However, since this not only protects the Al wiring 3, but also inhibits the thermal expansion of the Al wiring 3, the thickness of the SiON layer 21 is thickened to 50 to 200 nm.

Here, in the above-described third embodiment, although the interlayer insulating film is formed by a high-density plasma CVD method, the similar effects can be obtained when the interlayer insulating film is formed by ordinary plasma CVD method. The similar effects can also be obtained when an SiN film or plasma TEOS film is used as a buffer layer in place of the SiON film.

Fourth Embodiment

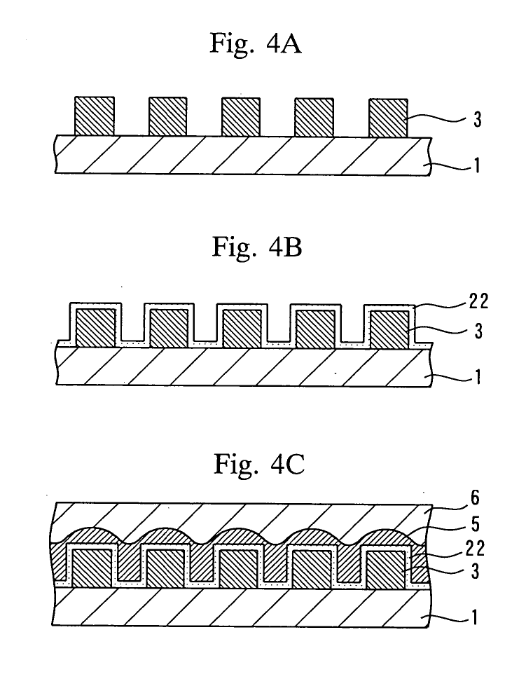

FIG. 4 shows a method of manufacturing a semiconductor device according to the fourth embodiment of the present invention. The same constituents as shown in FIG. 1 are denoted by the same reference numerals, and the description thereof will be omitted. First, as FIG. 4A shows, an Al wiring 3 is formed on a substrate 1.

Next, as FIG. 4B shows, an HDP-SIO film 22 is formed as a buffer layer by a high-density plasma CVD method at a low growing temperature of 450° C. or below so as to cover the Al wiring 3. Here, in order to adjust the growing temperature to 450° C. or below the flow rate of the cooling gas blown to the back of the substrate 1 is raised. The growing temperature is preferably 350 to 400° C. Furthermore, the thickness of the HDP-SIO film 22 is 50 to 200 nm.

Then, as FIG. 4C shows, an HDP-SIO film 5, which is an interlayer insulating film, is formed by a high-density plasma CVD method at a high growing temperature of 450° C. to 600C on the HDP-SIO film 22. Furthermore, an SiO₂ film 6 is formed by a plasma CVD method using TEOS and O₂ gas as reactive gases and planarized by CMP.

According to the method of manufacturing a semiconductor device as described above, since the Al wiring 3 is covered with the HDP-SIO film 22, the thermal expansion of the Al wiring 3 when the HDP-SIO film 5 is formed by the high-density plasma CVD method can be physically inhibited. Therefore, the occurrence of voids in the Al wiring 3 can be prevented;

Here, since the HDP-SIO film 22 is formed at a low growing temperature of 450° C. or below, no voids in the metal wiring due to the thermal expansion of the Al wiring 3 are produced. Also, in order to inhibit thermal expansion the thickness of the HDP-SIO film 22 is thickened to 50 to 200 nm. Although the HDP-SIO film 22, which is grown at a low temperature, has poor burying properties, this can be compensated by forming thereon the HDP-SIO film 5, which is grown at a high temperature.

Fifth Embodiment

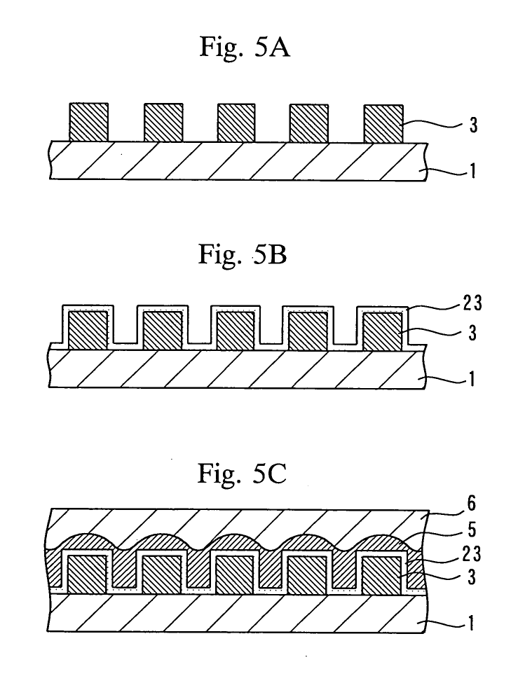

FIG. 5 shows a method of manufacturing a semiconductor device according to the fifth embodiment of the present invention. The same constituents as shown in FIG. 1 are denoted by the same reference numerals, and the description thereof will be omitted. First, as FIG. 5A shows, an Al wiring 3 is formed on a substrate 1.

Next, as FIG. 5B shows, an HDP-SIO film 23 is formed as a buffer layer by a high-density plasma CVD method having a lowered deposition/sputtering ratio (D/S ratio) so as to cover the Al wiring 3. The thickness of the HDP-SIO film 23 is 50 to 200 nm.

Then, as FIG. 5C shows, an HDP-SIO film 5, which is an interlayer insulating film, is formed on the HDP-SIO film 23 by a high-density plasma CVD method having a higher D/S ratio than the D/S ratio for the formation of the HDP-SIO film 23. Furthermore, an SiO₂ film 6 is formed by a plasma CVD method using TEOS and O₂ gas as reactive gases, and planarized by CMP.

According to the method of manufacturing a semiconductor device as described above, since the Al wiring 3 is covered with the HDP-SIO film 23, the thermal expansion of the Al wiring 3 when the HDP-SIO film 5 is formed by the high-density plasma CVD method can be physically inhibited. Therefore, the occurrence of voids in the Al wiring 3 can be prevented.

Here, since the D/S ratio, which is the deposition/sputtering ratio, is lowered when the HDP-SIO film 23 is formed, heat generation by the sputtering of Ar atoms in inhibited, and no voids in the metal wiring due to the thermal expansion of the Al wiring 3 are produced. Also, since sputtering is reduced, the shoulders of the Al wiring 3 are prevented from rounding. Furthermore, in order to inhibit thermal expansion, the thickness of the HDP-SIO film 23 is as thick as 50 to 200 nm. Since sputtering is reduced, the HDP-SIO film 23 has poor burying properties; however, this can be compensated by forming thereon the HDP-SIO film 5, which has good burying properties.

The features and advantages of the present invention may be summarized as follows.

As described above, when an interlayer insulating film is formed by a high-density plasma CVD method so as to cover a metal wiring, the thermal expansion of the metal wiring can be inhibited, and the occurrence of voids in the metal wiring can be prevented.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-381040, filed on Dec. 27, 2002 including specification, claims, drawings and summary, on which the Convention priority of the present application is based, are incorporated herein by reference in its entirety.

What is claimed is:

1. A semiconductor device comprising:
a substrate;
a metal wiring formed on the substrate and covered with the films of a high-melting-point metal immediately above and below; and
an interlayer insulating film formed by a plasma CVD method so as to cover the metal wiring.

2. A semiconductor device comprising:
a substrate;
an Al wiring formed on a substrate;
an Al compound layer formed on the side of the Al wiring; and
an interlayer insulating film formed by a plasma CVD method so as to cover the Al wiring and the Al compound layer.

3. The semiconductor device according to claim 2, wherein the Al compound layer is subjected to annealing in a nitrogen atmosphere to nitrogenize the side of the Al wiring.

4. The semiconductor device according to claim 2, wherein the Al compound layer is subjected to annealing in an oxygen atmosphere to oxidize the side of the Al wiring.

5. A semiconductor device comprising:
a substrate;
a metal wiring formed on a substrate;
a buffer layer formed so as to cover the metal wiring; and
an interlayer insulating film formed on the buffer layer by a plasma CVD method.

6. The semiconductor device according to claim 5, wherein any of an SiON film, an SiN film, and a plasma TEOS film is used as the buffer layer.

7. The semiconductor device according to claim 5, wherein the film thickness of the buffer layer is 50 to 200 nm.
